(19) United States
(12) Patent Application Publication
(10) Pub. No.: US 2025/0290989 A1
(43) Pub. Date: Sep. 18, 2025

(54) ELECTROCHEMICAL IMPEDANCE SPECTROSCOPY FOR A BATTERY

(71) Applicant: Cirrus Logic International Semiconductor Ltd., Edinburgh (GB)

(72) Inventors: Emmanuel MARCHAIS, Dripping Springs, TX (US); Markos KOSEOGLOU, Austin, TX (US)

(73) Assignee: Cirrus Logic International Semiconductor Ltd., Edinburgh (GB)

(21) Appl. No.: 18/967,032

(22) Filed: Dec. 3, 2024

Related U.S. Application Data
(60) Provisional application No. 63/564,549, filed on Mar. 13, 2024.

(51) Int. Cl. G01R 31/3842; G01R 31/36; G01R 31/389; H01M 10/48

(52) U.S. Cl. CPC G01R 31/3842; G01R 31/3648; G01R 31/389; H01M 10/482

(57) ABSTRACT

A system for performing electrochemical impedance spectroscopy for a battery, the system comprising: a switch operable to apply an AC stimulus signal to the battery; current monitor circuitry configured to be coupled to the battery and to provide a battery current signal indicative of a current through the battery; voltage monitor circuitry configured to be coupled to the battery and to output a battery voltage signal indicative of a voltage across at least one cell of the battery; a processing subsystem having a first input coupled to an output of the current monitoring circuitry and a second input coupled to an output of the voltage monitoring circuitry, wherein the processing subsystem is configured to determine an impedance of the at least one cell of the battery based on the battery current signal and the battery voltage signal while the AC stimulus signal is being applied to the battery.

### FIELD OF THE INVENTION

The present disclosure relates to a system and method for performing electrochemical impedance spectroscopy for a battery.

### BACKGROUND

Electrochemical Impedance Spectroscopy (EIS) is a measurement usually made in the frequency domain by applying a small (i.e. low-amplitude), typically sinusoidal, AC signal (which may be referred to as a perturbation) to a chemical system such as a cell, battery or battery pack to be measured. The applied signal may be a voltage signal or a current signal.

The impedance of the chemical system at any given frequency is related to processes that occur in the system at timescales corresponding to or similar to the duration of a cycle of the applied signal. For example, the impedance of the chemical system when the frequency f of the applied signal=20 Hz is related to processes that occur at timescales of the order of 0.05 s (as a duration t of a single cycle of the applied signal=0.05 s).

EIS is different from other ways of performing measurements that involve driving a system with relatively large steps or sweeps far from its equilibrium, since EIS uses small perturbations. Because the small signal applied to the system causes the system to depart from system equilibrium by only a small amount, the system can be modelled as a system with a linear response. Such modelling simplifies frequency analysis of the system.

EIS is typically performed by stepping or sweeping the applied signal through a wide range of frequencies while maintaining the amplitude of the applied signal constant. However, the linearization of such system models has shortcomings, in that it can lead to indistinguishable cases, especially for the system's nonlinear behavior, thus requiring the model to be based on nonlinear EIS (NLEIS) modelling or measurements.

Systems and devices such as battery cells, batteries and battery packs often operate far from equilibrium and exhibit nonlinear behavior. For example, battery impedance measurements can be performed and are useful for monitoring and regulating battery performance degradation during its charge cycle.

Electrochemical impedance spectrum (EIS) measurements can be used for measuring characteristics such as the impedance of a chemical or electrochemical system such as a battery cell, battery or battery pack.

### SUMMARY

According to a first aspect, the invention provides a system for performing electrochemical impedance spectroscopy for a battery, the system comprising: a switch operable to apply an AC stimulus signal to the battery; current monitor circuitry configured to be coupled to the battery and to provide a battery current signal indicative of a current through the battery; voltage monitor circuitry configured to be coupled to the battery and to output a battery voltage signal indicative of a voltage across at least one cell of the battery; a processing subsystem having a first input coupled to an output of the current monitoring circuitry and a second input coupled to an output of the voltage monitoring circuitry, wherein the processing subsystem is configured to determine an impedance of the at least one cell of the battery based on the battery current signal and the battery voltage signal while the AC stimulus signal is being applied to the battery.

The battery, switch, voltage monitor circuitry, current monitor circuitry and processing subsystem may be parts of a battery pack.

The battery, voltage monitor circuitry, current monitor circuitry and processing subsystem may be parts of a battery pack. The switch may be external to the battery pack.

The current monitor circuitry and the voltage monitor circuitry may be parts of a fuel gauge subsystem of the battery pack. The switch may be part of a protection subsystem of the battery pack. In normal operation of the battery pack the protection subsystem may be operable to control current into and out of the battery.

The battery may comprise the at least one cell and a current sense resistor coupled in series with the at least one cell.

The system may further comprise control circuitry configured to control operation of the switch based on a reference current or a reference voltage input to the control circuitry.

The reference current may comprise an AC component and a DC component. The control circuitry may be configured to control operation of the switch to minimise a difference between the reference current and the current through the battery.

The system may further comprise a charging waveform generator configured to provide the AC component of the reference current.

The system may further comprise coulomb counter circuitry configured to output a signal indicative of a state of charge of the battery. The DC component of the reference current may be based on the signal output by the coulomb counter circuitry.

The reference voltage may comprise an AC component and a DC component. The linear charge loop control circuitry may be configured to control operation of the switch to minimise a difference between the reference voltage and the voltage across the at least one cell of the battery.

The system may further comprise a charging waveform generator configured to provide the AC component of the reference voltage.

The system may further comprise a low pass filter operative to generate a filter output signal indicative of the voltage across the at least one cell of the battery. The DC component of the reference voltage may be based on the filter output signal or on a predetermined target voltage across the at least one cell of the battery.

The system may further comprise a shunt path, the shunt path comprising a shunt switch coupled to the at least one cell of the battery and configured to, when activated, shunt current around the at least one cell of the battery.

The battery may comprise a plurality of cells coupled in series. The battery, voltage monitor circuitry, current monitor circuitry and processing subsystem may be parts of a battery pack. The shunt path may comprise one or more switches of a cell balancing circuit of the battery pack.

The battery may comprise the plurality of cells and a current sense resistor coupled in series with the plurality of cells. The shunt path may comprise a further switch coupled in parallel with the current sense resistor and to the one or more switches of the cell balancing circuit.

The shunt path may comprise a shunt resistor coupled in series with the shunt switch.

The shunt switch may be operable to provide the AC stimulus signal to the battery.

The system may further comprise: control circuitry; and a discharge waveform generator. The control circuitry may be configured to receive a discharge waveform from the discharge waveform generator and to control the shunt switch based on the discharge waveform to apply an AC discharge signal to the battery as the AC stimulus signal.

The control circuitry may be configured to configured to control operation of the shunt switch to minimise a difference between the discharge waveform and the current through the battery.

The current sense circuitry may comprise: the current sense resistor; and first analog to digital converter (ADC) circuitry having an input coupled to the current sense resistor and configured to generate a digital output signal indicative of the current through the battery.

The current sense circuitry may further comprise analog front end (AFE) circuitry having an input coupled to the current sense resistor and an output coupled to the input of the first ADC circuitry. The AFE circuitry may be configured to receive a voltage across the current sense resistor and output an analog AFE output signal indicative of the current through the battery.

The voltage monitor circuitry may comprise: first multiplexer circuitry having a plurality of inputs and first and second outputs. The first multiplexer circuitry may be configured to selectively couple one of its inputs to its first output and another of its inputs to its second output. The voltage monitor circuitry may further comprise second ADC circuitry having first and second inputs coupled to the first and second outputs, respectively, of the first multiplexer circuitry. The second ADC circuitry may be configured to output a digital signal indicative of one of: a voltage across a cell of the one or more cells of the battery; or a voltage across the battery; or a voltage of a battery pack of which the battery forms part, dependent upon which of the inputs of the first multiplexer circuitry are coupled to the first and second outputs of the first multiplexer circuitry.

The battery may comprise a plurality of cells coupled in series. The voltage monitor may comprise a plurality of instances of ADC circuitry, each instance of ADC circuitry having first and second inputs coupled to different nodes of the battery, so as to generate respective digital output signals representative of approximations of voltages at the different nodes of the battery.

According to a second aspect, the invention provides a battery back comprising the system of the first aspect.

According to a third aspect, the invention provides a host device comprising the system of the first aspect. The host device may comprise a laptop, notebook, netbook or tablet computer, a gaming device, a games console, a controller for a games console, a virtual reality (VR) or augmented reality (AR) device, a mobile telephone, a portable audio player, a portable device, an accessory device for use with a laptop, notebook, netbook or tablet computer, a gaming device, a games console a VR or AR device, a mobile telephone, a portable audio player or other portable device.

According to a fourth aspect, the invention provides a system for performing electromagnetic impedance spectroscopy for a battery of a battery pack which comprises a switch operable to control a flow of current into and out of the battery, the system comprising: control circuitry configured to control the switch to apply an AC stimulus signal to the battery.

The system may further comprise: current monitor circuitry configured to be coupled to the battery and to provide a battery current signal indicative of a current through the battery; voltage monitor circuitry configured to be coupled to the battery and to output a battery voltage signal indicative of a voltage across at least one cell of the battery; a processing subsystem having a first input coupled to an output of the current monitoring circuitry and a second input coupled to an output of the voltage monitoring circuitry, wherein the processing subsystem is configured to determine an impedance of the at least one cell of the battery based on the battery current signal and the battery voltage signal while the AC stimulus signal is being applied to the battery.

Throughout this specification the word “comprise”, or variations such as “comprises” or “comprising”, will be understood to imply the inclusion of a stated element, integer or step, or group of elements, integers or steps, but not the exclusion of any other element, integer or step, or group of elements, integers or steps.

### BRIEF DESCRIPTION OF DRAWINGS

Embodiments of the invention will now be described, strictly by way of example only, with reference to the accompanying drawings, of which:

FIG. 1 is a schematic representation of an example EIS measurement system;

FIG. 2 is a schematic diagram showing a system for performing EIS for a battery according to the present disclosure;

FIG. 3 is a is a schematic diagram showing an alternative configuration of the system 200 of FIG. 2;

FIG. 4 is a schematic diagram showing an alternative system for performing EIS for a battery according to the present disclosure;

FIG. 5 is a schematic diagram showing an alternative system for performing EIS for a battery according to the present disclosure;

FIG. 6 is a schematic diagram showing a further alternative system for performing EIS for a battery according to the present disclosure; and

FIG. 7 is a schematic diagram showing another alternative system for performing EIS for a battery according to the present disclosure.

### DETAILED DESCRIPTION

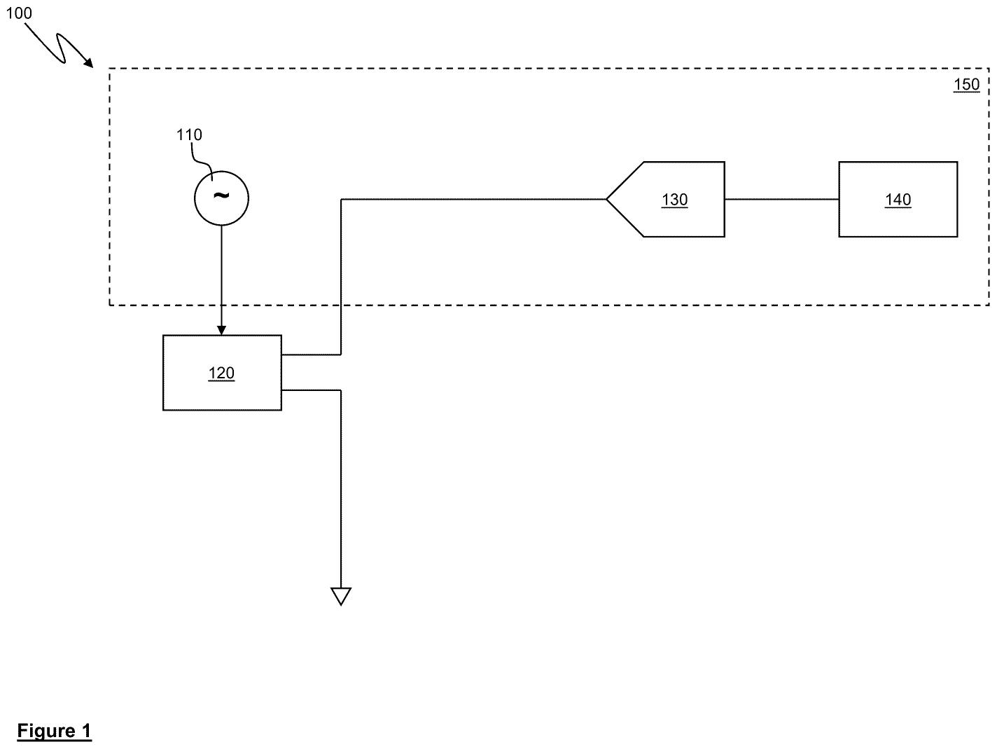

FIG. 1 is a schematic representation of an example EIS measurement system.

The example EIS measurement system shown generally at 100 in FIG. 1 comprises signal generator circuitry 110 configured to generate an alternating current (AC) stimulus current signal (sometimes also referred to as an EIS driving current) for application to a component 120. The component 120 may be, for example, a cell, battery, battery pack or other chemical or electrochemical system. The AC stimulus signal is typically applied to a rested component 120. It is to be noted that the term component, as used in the present disclosure, encompasses components that consist of a single element (e.g. a battery, cell or other chemical or electrochemical system) as well as components that consist of a plurality of elements (e.g. a battery pack comprising a plurality of individual battery cells) assembled to form a component part or subsystem of a larger system.

The AC stimulus current signal may be a chirp signal or other signal whose frequency varies (e.g. is swept or stepped) over a defined frequency range, e.g. 50 kHz to 50 mHz or less (e.g. 50 kHz to 1 mHz), over a defined period of time. The peak amplitude of the AC stimulus current signal is small, e.g. of the order of 50 mA.

When the AC stimulus current signal is applied to the component 120, the component 120 generates an EIS measurement voltage signal in response. Analog to digital converter (ADC) circuitry 130 is coupled to the component 120 to receive this EIS measurement voltage signal and to convert it into a digital signal which is output to EIS processing circuitry 140. The EIS processing circuitry 140 processes the digitised EIS measurement signal to generate one or more EIS measurement outputs, which may be, for example, one or more output signals indicative of an impedance of the component 120.

This approach to performing EIS measurements may be referred to as “Galvanostatic EIS measurement”.

In an alternative approach, a small AC stimulus voltage signal (e.g. having a peak amplitude of the order of 5 mV) having a frequency that varies (e.g. is swept or stepped) over a defined frequency range, e.g. 50 kHz to 50 mHz or less (e.g. 50 kHz to 1 mHz), over a defined period of time is applied to the component 120. A digital signal indicative of a resulting EIS measurement current is processed by the EIS processing circuitry 140 to generate one or more EIS measurement outputs which may be, for example, one or more output signals indicative of an impedance of the component 120. This approach may be referred to as “Potentiostatic EIS measurement”.

EIS measurement systems of the kind described above with reference to FIG. 1 may be used to perform EIS measurements of a rested component in a laboratory environment. This approach may provide consistent EIS measurement results, and may also facilitate interpretation of the EIS measurement results.

The EIS measurement outputs can be used, for example, to help correlate an impedance of the component 120 to its state of health, or to identify parameters of a model of the component 120.

In an alternative approach which may be used, for example, when it is necessary or desirable to perform EIS measurements of a battery (or other component) while the battery is charging, a small AC current of the kind described above (e.g. of peak amplitude of the order of 50 mA) is biased by (e.g. combined with) a direct current to generate an AC stimulus current signal, which can be applied to the battery. A frequency of this AC stimulus current signal is varied (e.g. is swept or stepped) over a defined frequency range, e.g. 50 kHz to 50 mHz or less (e.g. 50 kHz to 1 mHz), over a defined period of time. A digital signal representing an EIS measurement voltage generated by the battery in response to the applied AC stimulus current signal is processed by EIS processing circuitry 140 of the kind described above to generate one or more EIS measurement outputs of the kind described above. This approach may be referred to as “Biased EIS”.

Because the AC stimulus current signal includes a DC bias component, the current flow in this alternative approach is unidirectional, i.e. an alternating current having a positive amplitude flows into the battery. If the DC bias component is small and any change in a state of charge (SoC) of the battery is small over the defined period of time for which the AC stimulus current signal is applied to the battery, this approach can approximate the laboratory method described above.

A further alternative approach to performing EIS measurements is to measure a voltage across the battery (battery voltage) and a current through the battery (battery current) as the frequency of a voltage across a load (load voltage) coupled to the battery or a current through the load (load current) varies over a an arbitrarily wideband frequency range. The impedance of the battery across the frequency range can be determined using the measured battery voltage and current. In such systems the amplitude of the load current and/or load voltage may be higher than the amplitude of the stimulus signal in the approaches discussed above. This approach may be referred to as “Dynamic EIS”.

In some EIS measurement systems that are used for performing EIS measurements for cells, batteries or battery packs (which will be referred to as batteries for brevity), the signal generator circuitry 110 is replaced by a controllable power sink that modulates the output voltage or current of the battery to achieve the effect of applying a stimulus signal to the battery.

Referring again to FIG. 1, it may be desirable to provide an integrated circuit (IC) or chip 150 having a built-in EIS measurement system comprising the signal generator circuitry 110 (or alternatively a controllable power sink), ADC circuitry 130 and EIS processing circuitry 140.

However in an IC or chip having such a built-in EIS system, measurement errors can arise, due to temperature fluctuations of the IC die of the IC or chip 150 on which the EIS system is implemented.

In particular, for an IC or chip having a built-in EIS system that includes a controllable power sink, power is dissipated by the controllable power sink to surrounding areas of the IC die, which may cause the temperature of the ADC circuitry 130 and/or the EIS processing circuitry 140 to fluctuate, leading to measurement errors.

The present disclosure proposes to dissipate power in a component external to an IC that incorporates sensing and/processing circuitry to modulate a voltage or current of a battery or battery pack, in order to minimise or at least reduce the adverse effects on the sensing and/or processing circuitry of heat dissipated by the power dissipating component.

In some examples, power is dissipated in a pre-existing component of a battery pack. Dissipating power in a component that already exists in the battery pack for the purpose of performing EIS measurements of the battery pack avoids additional cost and complexity associated with providing an additional component (and any associated circuitry) to dissipate power for the purpose of performing EIS measurements of the battery pack.

In particular, some examples of the present disclosure power is dissipated in a power or protection switch such as a field effect transistor (FET) of the battery pack. Such protection switches can tolerate sufficient power dissipation (e.g. up to half a Watt) to provide EIS functionality for the battery pack.

In other examples, power is dissipated in a switch such as a FET that is not part of the battery pack and is external to sensing and/or processing circuitry.

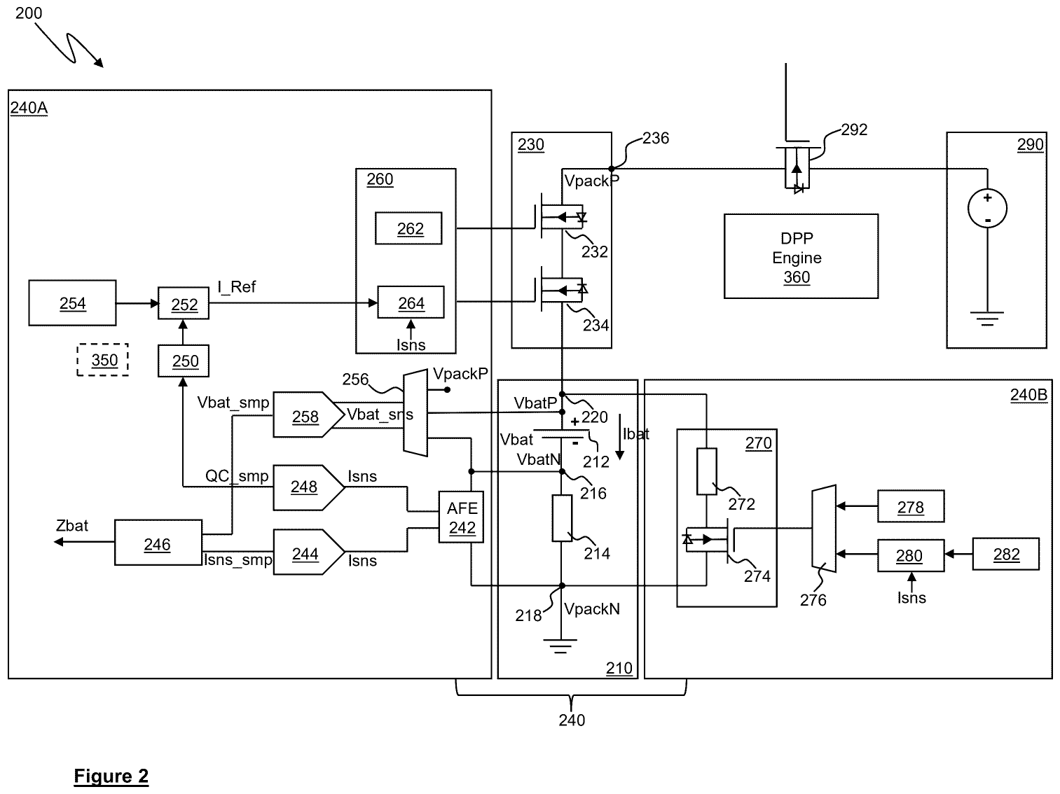

FIG. 2 is a schematic diagram showing a system for performing EIS for a battery according to the present disclosure.

As shown generally at 200 in FIG. 2, the system 200 can be coupled to a battery 210 including a battery cell or cell stack (comprising two or more battery cells coupled in series) 212. A current sense resistor 214 is coupled in series between a negative terminal 216 of the battery cell or cell stack 212 and a ground or negative terminal 218 of the battery 210.

The battery 210 is coupled (at a positive terminal 220 of the battery cell or cell stack 212) to a protection subsystem 230 comprising a first power or protection switch 232 and a second power or protection switch 234. The first and second power or protection switches 232, 234 in this example are FETs. The first and second power or protection switches 232, 234 are coupled in series between a positive terminal 236 of the protection subsystem 230 and a positive terminal 226 of the battery 210. The first and second power or protection switches 232, 234 are operable to control current into and out of the battery 210.

The first power or protection switch 232 is operable to control discharging of the battery 210, and thus may be referred to as a discharging switch or a discharging FET. When the first power or protection switch 232 is switched off, it prevents current from flowing out of the battery, and thus prevents discharging of the battery 210.

The second power or protection switch 234 is operable to control charging of the battery 210 and thus may be referred to as a charging switch or a charging FET. When the second power or protection switch 234 is switched off, it prevents current from flowing into the battery 210 and thus prevents charging of the battery 210.

A fuel gauge subsystem 240 is coupled to the battery 210. For illustrative purposes the fuel gauge subsystem 240 is shown in FIG. 2 as comprising first and second fuel gauge subsystem blocks 240A, 240B, but it will be appreciated by those skilled in the art that in a practical implementation of the system 200 the fuel gauge subsystem 240 need not be arranged as two separate blocks as shown in FIG. 2.

The fuel gauge subsystem 240 comprises analog front end (AFE) circuitry 242 having a first input coupled to the negative terminal 216 of the battery cell or cell stack 212 and a second input coupled to the ground or negative terminal 218 of the battery 210, such that a voltage across the current sense resistor 214 of the battery 210 (which is indicative of a current through the current sense resistor 214 and thus a current through the battery 210) is received by the AFE circuitry 242. The AFE circuitry 242 is configured to condition (e.g. amplify and/or filter) the received voltage to generate an analog AFE output signal Isns indicative of the current through the battery 210.

A first output of the AFE circuitry 242 coupled to an input of first analog to digital converter (ADC) circuitry 244, which may also be referred to as current sense ADC circuitry. The AFE circuitry 242 is configured to output the analog AFE output signal Isns indicative of the current through the battery 210 to the first ADC circuitry 244.

An output of the first ADC circuitry 244 is coupled to a first input of a processing subsystem 246, such that the first ADC circuitry 244 is operative to output a digital signal Isns_smp indicative of the current through the battery 210 to the processing subsystem 246.

In an alternative arrangement the AFE circuitry 242 may be omitted, and the first (current sense) ADC circuitry 244 may have differential first and second inputs coupled, respectively, to the negative terminal 216 of the battery cell or cell stack 212 and to the ground or negative terminal 218 of the battery 210. In such an arrangement the first ADC circuitry 244 is operative to output a digital signal Isns_smp indicative of the current through the battery 210 to the processing subsystem 246.

Thus, in examples that include the AFE circuitry 242, the current sense resistor 214 and the AFE circuitry 242, either alone or in combination with the first (current sense ADC) circuitry 244, constitute current monitor circuitry configured to be coupled to the battery and to provide a battery current signal (the analog AFE output signal Isns or the digital signal Isns_smp output by the first ADC circuitry 244) indicative of a current through the battery 210.

In examples that omit the AFE circuitry 242, the current sense resistor 214 and the first (current sense) ADC circuitry 244 constitute current monitor circuitry configured to be coupled to the battery and to provide a battery current signal (the digital signal Isns_smp output by the first ADC circuitry 244) indicative of a current through the battery 210.

A second output of the AFE circuitry 242 is coupled to an input of coulomb counter circuitry 248. The coulomb counter circuitry 248 is schematically represented in FIG. 2 as an ADC, but it will be appreciated by those of ordinary skill in the art that a practical implementation of the coulomb counter circuitry 248 may include additional elements such as an integrator in addition to an ADC.

The coulomb counter circuitry 248 is operative to receive the analog signal Isns indicative of the current through the battery from the AFE circuitry 242 and to output a digital signal QC_smp indicative of a level of discharge of the battery 210 relative to a reference level of charge of the battery 210.

An output of the coulomb counter circuitry 248 is coupled to an input of an offset controller 250, which has an output coupled to a first input of an adder 252. The offset controller 250 is configured to output a DC bias current to the adder 252. The level of the bias current output by the offset controller 250 is dependent upon the output of the coulomb counter circuitry 248.

A second input of the adder 252 is coupled to an output of a charging waveform generator 254, which is configured to generate and output an AC current signal to the adder 252. The adder 252 adds the AC current signal to the DC bias current to generate a reference current I_Ref.

The fuel gauge subsystem 240 further comprises first multiplexer circuitry 256 having first, second and third inputs and first and second outputs.

The first input of the first multiplexer circuitry 256 is coupled to the negative terminal 216 of the battery cell or cell stack 212 so as to receive a voltage VbatN at the negative terminal 216. The second input of first multiplexer circuitry 256 is coupled to the positive terminal 220 of the battery cell or cell stack 212 so as to receive a voltage VbatP at the positive terminal 220. The third input of the first multiplexer circuitry 256 is coupled to a positive terminal of a battery pack in which the battery 210, protection subsystem 230 and fuel gauge subsystem 240 are incorporated, so as to receive a voltage VpackP at the positive terminal of the battery pack.

The first and second outputs of the first multiplexer circuitry 256 are coupled to differential first and second inputs of second ADC circuitry 258 (which may be referred to as a voltage sense ADC). An output of the second ADC circuitry 258 is coupled to a second input of the processing subsystem 246.

The first multiplexer circuitry 256 is operative to couple its first input to its first output, and to selectively couple its second or third input to its second output (in response to a suitable control signal), such that a differential output voltage Vbat_sns output by the first multiplexer circuitry 256 is equal to a difference between the voltages at the selected inputs of the first multiplexer circuitry 256.

Thus, when the first and second inputs of the first multiplexer circuitry 256 are coupled to its outputs, the voltages VbatN and VbatP are supplied to the differential first and second inputs of the second ADC circuitry 258, such that a digital signal Vbat_smp output by the second ADC circuitry 258 is indicative of the voltage Vbat across the battery cell or cell stack 212 (i.e. VbatP-VbatN).

When the first and third inputs of the first multiplexer circuitry 256 are coupled to its outputs, the voltages VbatN and VpackP are supplied to the differential first and second inputs of the second ADC circuitry 258, such that the digital signal Vbat_smp output by the second ADC circuitry 258 is indicative of an approximation of a voltage across the battery pack (i.e. VpacktP-VbatN).

The first multiplexer circuitry 256, either alone or in combination with the second (voltage sense) ADC circuitry 258, thus constitutes voltage monitor circuitry configured to be coupled to the battery and to provide a battery voltage signal (the differential analog signal Vbat_sns output by the first multiplexer circuitry 256 to the second ADC circuitry 258 or the digital signal Vbat_smp output by the second ADC circuitry 258) indicative of a voltage across at least one cell of the battery 210.

Thus, the processing subsystem 246 receives a first digital input signal Isns_smp indicative of the current Ibat through the battery cell or cell stack 212 and a second digital input signal Vbat_smp indicative of the battery voltage Vbat (or the battery pack voltage).

The processing subsystem 246 is configured to generate an output Zbat indicative of the impedance of the battery cell or cell stack 212, based on the received digital input signals, by dividing the battery voltage Vbat indicated by the second digital input signal Vbat_smp by the battery current Ibat indicated by the first digital input signal Isns_smp.

The system 200 further includes driver controller circuitry 260 (shown in FIG. 2 as part of the fuel gauge subsystem 240) configured to control operation of the first and second protection switches 232, 234. The driver controller circuitry 260 is configured to control operation of the second protection switch 234 to implement different operating modes of the second protection switch 234.

The driver controller circuitry 260 comprises on/off control circuitry 262 and linear charge loop control circuitry 264.

The on/off control circuitry 262 is configured to control operation of the first protection switch 232, and has an output coupled to a control terminal (e.g. a gate) of the first protection switch 232.

The linear charge loop control circuitry 264 is configured to control operation of the second protection switch 234, and has an output coupled to a control terminal (e.g. a gate) of the second protection switch 234. A first input of the linear charge loop control circuitry 264 is coupled to the output of the adder 252 so as to receive the reference current I_Ref. A second input of the linear charge loop control circuitry 264 is coupled to an output of the AFE circuitry 242 so as to receive the analog signal Isns indicative of the current through the battery 210.

The operating modes of the second protection switch 234 include: an off mode or state in which the second protection switch 234 is switched off (in response to a suitable control signal output by the linear charge loop control circuitry 264) to prevent charging of the battery 210; an on mode or state in which the second protection switch 234 is switched on to provide a low-impedance path for bidirectional current flow into and out of the battery 210; and a charge current control mode in which the impedance of the second protection switch 234 is controlled to allow a fixed charging current to flow into the battery 210, with the charging current being independent of the battery voltage Vbat or the battery pack voltage VpackP.

In the charge current control mode, the linear charge loop control circuitry 264 is operative to adjust the control signal output to the control terminal (e.g. gate) of the second protection switch 234 based on the sensed current signal Isns, to regulate the charging current so as to maintain the charging current at a predetermined level (or within predetermined upper and lower limits).

In addition, the second protection switch 234 may be operative in a voltage control mode in which the linear charge loop control circuitry 264 adjusts the control signal output to the control terminal (e.g. gate) of the second protection switch 234 to control one of the Vbat, VpackP or (VpackP-Vbat) voltages.

The system 200 further includes a controllable shunt path 270 (shown in FIG. 2 as being part of the fuel gauge subsystem 240), coupled in parallel with the series combination of the battery cell or cell stack 212 and current sense resistor 214. It is to be understood, however, that in other examples the controllable shunt path 270 may be omitted.

The controllable shunt path 270 in the example shown in FIG. 2 comprises a shunt resistor 272 and a shunt switch 274 (e.g. a FET) coupled in series between the positive terminal 220 of the battery cell or cell stack 212 and the ground or negative terminal 218 of the battery 210. Thus, when the shunt switch 274 is activated (e.g. switched on), a current path through the shunt resistor 272 is created and some current is shunted around the battery 210 through the shunt resistor 272.

In alternative examples the shunt resistor 272 may be omitted, such that current is shunted around the battery 210 through the shunt switch 274 when the shunt switch 274 is switched on. In such examples the impedance of the shunt switch 274 may be controlled by a suitable control signal supplied to a control terminal (e.g. a gate) of the shunt switch 274 to control the amount of current in the controllable shunt path 270.

The control (e.g. gate) terminal of the shunt switch 274 is coupled to an output of second multiplexer circuitry 276. A first input of the second multiplexer circuitry 276 is coupled to an output of second on/off control circuitry 278. A second input of the second multiplexer circuitry 276 is coupled to an output of linear discharge loop control circuitry 280. A first input of the linear discharge loop control circuitry 280 is coupled to a discharge waveform generator 282, and a second input of the linear discharge loop control circuitry 280 is coupled to an output of the AFE circuitry 242 so as to receive the sense current signal Isns.

The second multiplexer circuitry 276 is configured to selectively couple its output to either its first input or its second input. When first input of the second multiplexer circuitry 276 is coupled to its output, the shunt switch 274 is controlled by the second on/off control circuitry 278, whereas when the second input of the second multiplexer circuitry 276 is coupled to its output, the shunt switch 274 is controlled by the linear discharge loop control circuitry 280.

The battery 210 of FIG. 2 can be coupled to a charger 290, which is external to the battery pack that comprises the battery 210, protection subsystem 230, and fuel gauge subsystem 240. The charger 290 can be coupled to the battery pack via the positive terminal 236 of the protection subsystem 230 of the battery pack, and is configured to supply a charging current to the battery 210.

A system load (not shown in FIG. 2 for the sake of clarity), i.e. a load that draws current from the battery pack, e.g., one or more components, systems or subsystems of a host device in which the battery pack is incorporated, can also be coupled to the battery pack via the positive terminal 236 of the protection subsystem 230.

The system 200 of FIG. 2 is operable to perform galvanostatic EIS of the battery 210, by applying a small AC stimulus current signal to the battery 210.

In a first method that can be performed by the system 200 illustrated in FIG. 2, the AC stimulus current signal is a biased AC stimulus current signal, comprising a DC current and a small AC current (e.g. having a peak amplitude of the order of 50-100 mA). The AC current may be of a fixed frequency, or may include a plurality of different frequencies. Alternatively, the frequency of the AC current may vary (e.g. may be swept or stepped) over a defined range (e.g. e.g. 50 kHz to 1 mHz) over a defined period of time.

With the charger 290 connected to the battery 210 and driving a battery pack voltage Vpack higher than the battery voltage Vbat, the system 200 operates the second protection switch 234 in its charge current control mode to allow a fixed charging current (which may have both DC and AC components) to flow into the battery 210. In this mode the first protection switch 232 may be switched on, and/or a body diode of the first protection switch 232 may conduct the charging current, and a voltage at an output terminal (e.g. a drain) of the first protection switch 232 is approximately equal to the battery pack voltage VpackP, or VPackP-Vdiode, in the case where the body diode of the first protection switch 232 is conducting, where Vdiode is a voltage drop across the body diode of the first protection switch 232.

In the example shown in FIG. 2, the analog signal Isns, which is indicative of a current Ibat through the battery 210, is fed back to the linear charge loop control circuitry 264. However, the present disclosure also extends to alternative examples in which the digital signal isns_smp is fed back to the linear charge loop control circuitry 264.

The charging waveform generator 254 generates the small AC current referred to above and outputs it to the adder 252. The adder 252 adds the small AC current to a DC bias current output by the offset controller 250 to generate the reference current I_Ref, which is output to the linear charge loop control circuitry 264.

The linear charge loop control circuitry 264 outputs a control signal to the control terminal (e.g. gate) of the second protection switch 234 to control the current Ibat through the battery 210. The linear charge loop control circuitry 264 is configured to control the second protection switch 234 to minimise a difference between the reference current I_Ref and current through the battery 210 (as indicated by the sensed current signal Isns) irrespective of the battery pack voltage Vpack. As the reference current I_Ref is a biased AC current signal (comprising the DC bias current and the small AC current), the result of this control of the second protection switch 234 is that a biased small amplitude AC stimulus signal is applied to the battery 210. The second protection switch 234 is thus controlled by the linear charge loop control circuitry 264 to modulate the current Ibat through the battery 210.

The controllable shunt path 270 may be activated to shunt at least some of the DC charging current around the battery 210, such that the current Ibat through the battery 210 is a purely AC signal.

While the biased small amplitude AC stimulus signal is being applied to the battery 210, the processing subsystem 246 generates one or more impedance measurements for the battery 210 based on the digital signals output by the first (current sense) ADC circuitry 244 and the second (voltage sense) ADC circuitry 258.

Thus, the above-described first method performs biased EIS on the battery 210, or bias-free EIS if the controllable shunt path 270 shunts all the DC charging current around the battery 210.

In a variant of the first method, instead of controlling the second protection switch 234, the linear charge loop control circuitry 264 may control an external switch 292 (i.e. a switch such as a FET that is part of the system 200 but is external to the battery 210 and external to a battery pack that incorporates the battery 210, protection subsystem 230 and fuel gauge subsystem 240) to control or modulate the current Ibat through the battery 210, thus applying an AC stimulus signal to the battery.

In such a variant, the output of the linear charge loop control circuitry 264 may be coupled to a control (e.g. gate) terminal of the external switch 292 and decoupled from the control terminal of the second protection switch 234 when the first method is being performed. In this variant, the first and second protection switches 232, 234 are switched on while the first method is being performed. In the example system 200 illustrated in FIG. 2, the external switch 292 is provided in a current path from the charger 290 to the positive terminal 236 of the protection subsystem 230.

In a second method that can be performed by the system 200 illustrated in FIG. 2, a shunt current through the controllable shunt path 270 is modulated to generate an AC battery discharge current to apply an AC stimulus signal to the battery 210.

In this method, the discharge waveform generator 282 generates an AC discharge waveform, which is output to the linear discharge loop control circuitry 280, which also receives the current signal Isns indicative of the current through the battery 210. The second multiplexer circuitry 276 couples its second input to its output, such that a signal output by the linear discharge loop control circuitry 280 is output to the control terminal (e.g. gate) of the shunt switch 274.

The linear discharge loop control circuitry 280 is operative to minimise a difference between the AC discharge waveform and the sensed current signal Isns. As the AC discharge waveform is an AC signal, the result of this control of the shunt switch 274 is that a small amplitude AC discharge signal is applied to the battery 210, which has a similar effect as applying a biased AC stimulus signal to the battery 210.

While the small amplitude AC discharge signal is being applied to the battery 210, the processing subsystem 246 generates one or more impedance measurements for the battery 210 based on the digital signals output by the first (current sense) ADC circuitry 244 and the second (voltage sense) ADC circuitry 258.

Thus, the above-described method also performs biased EIS on the battery 210.

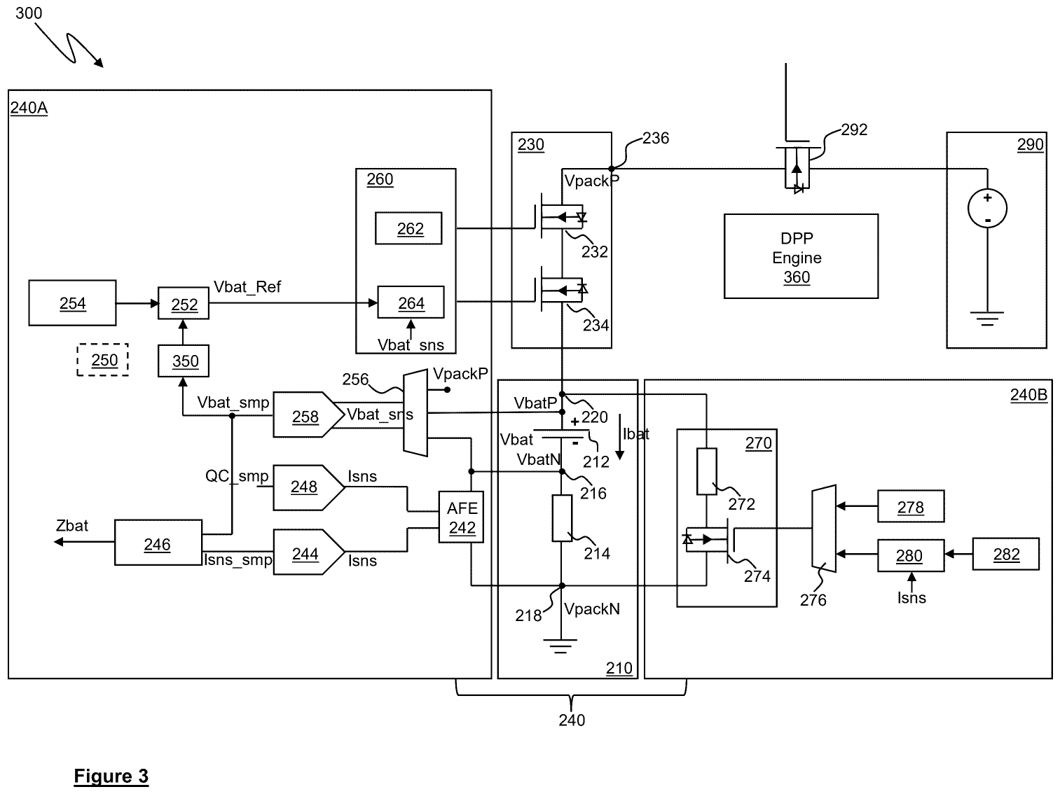

FIG. 3 is a schematic diagram showing an alternative configuration of the system 200 for performing EIS for a battery according to the present disclosure.

The alternative configuration, shown generally at 300 in FIG. 3, includes a number of features in common with the system 200 of FIG. 2. Such common features are denoted by common reference numerals in FIGS. 2 and 3, and will not be described again in detail here, for the sake of clarity and brevity.

The alternative configuration 300 of FIG. 3 differs from the configuration of the system 200 of FIG. 2 in that in the alternative configuration 300, the offset controller 250 is not used. Thus, the output of the coulomb counter circuitry 248 is shown in FIG. 3 as not being coupled to any other element.

Additionally, in the alternative configuration 300 of FIG. 3, the output of the second ADC circuitry 258 is coupled to an input of a low pass filter 350, which is configured to filter the digital signal Vbat_smp and to output a filter output signal indicative of the Voltage Vbat across the battery cell or cell stack 212, or indicative of the battery pack voltage, depending on the configuration of the inputs and outputs of the first multiplexer circuitry 256. An output of the low pass filter 350 is coupled to the first input of the adder 252. Further, the charging waveform generator 254 is configured to generate and output a small AC voltage signal (e.g. having a peak amplitude of the order of 2 mV) to the second input of the adder 252. The small AC voltage signal may be of a fixed frequency, or may include a plurality of different frequencies. Alternatively, the frequency of the AC voltage signal may vary (e.g. may be swept or stepped) over a defined range (e.g. e.g. 50 kHz to 1 mHz) over a defined period of time.

The adder 252 is thus configured to add the small AC voltage signal output by the charging waveform generator 254 to a DC reference voltage received from the low pass filter 350 to generate a battery reference voltage Vbat_Ref, which is output to the linear charge loop control circuitry 264.

In the example shown in FIG. 3, the linear charge loop control circuitry 264 receives the signal Vbat_sns indicative of the voltage Vbat across the battery cell or cell stack 212, and is operative to control the second protection switch 234 so as to minimise a difference between the reference voltage Vbat_Ref and the voltage Vbat across the battery cell or cell stack 212, as indicated by the signal Vbat_sns. However, the present disclosure also encompasses alternative examples in which the linear charge loop control circuitry 264 receives the digital signal Vbat_smp instead of the analog signal Vbat_sns.

The alternative configuration 300 can be used to perform bias free potentiostatic EIS on a battery. Here, bias free potentiostatic EIS is defined as a potentiostatic EIS that does not materially change the state of charge (SoC) of the battery, that is, a bias voltage exists but remains constant between the start and the end of the EIS.

The alternative configuration 300 can perform a method that uses a voltage control loop to perform such a bias free EIS.

With the charger 290 connected to the system 200 and controlling the voltage VPack supplied to an input (e.g. source) terminal of the first protection switch 232, the system 200 operates the second protection switch 234 in its voltage current control mode to control a voltage (typically the battery voltage Vbat). The shunt path 270 may be activated by providing suitable control signals to the control (e.g. gate) terminal of the shunt switch 274.

A digital signal Vbat_smp indicative of the open circuit voltage (OCV) Vbat (=VbatP-VbatN) of the cell or cell stack 212 is output by the second ADC circuitry 258 to the low pass filter 350. A filtered version of this signal is output, as a DC reference voltage, to the first input of the adder 252, which generates the battery reference voltage signal Vbat_Ref by adding the small AC voltage signal output by the charging waveform generator 254 to the DC reference voltage output by the low pass filter 350.

The battery reference voltage signal Vbat_Ref is output to the linear charge loop control circuitry 264, which also receives the signal Vbat_sns indicative of the voltage across the cell or cell stack 212. The linear charge loop control circuitry 264 outputs a control signal to the control terminal (e.g. gate) of the second protection switch 234 to modulate a voltage at the control terminal of the second protection switch 234.

The linear charge loop control circuitry 264 can thus control the voltage at an output (e.g. source) terminal of the second protection switch 234, and hence controls the voltage VbatP at the positive terminal 220 of the battery cell or cell stack 212 directly, or alternatively can control the voltage across the series combination of the first and second protection switches 232, 234 (e.g. a source-to-source voltage, where the first and second protection switches are FETs).

As noted above, in this method the linear charge loop control circuitry 264 is operative to control the second protection switch 234 so as to minimise a difference between the reference voltage Vbat_Ref and the voltage Vbat across the battery cell or cell stack 212, as indicated by the signal Vbat_sns.

As the battery reference voltage Vbat_Ref includes a small AC voltage component in addition to a reference DC voltage, the control signal output by the linear charge loop control circuitry 264 causes a small AC voltage (i.e. a small AC stimulus voltage signal) to be supplied to the cell or cell stack 212, in addition to a DC voltage equal to the OCV of the battery cell or cell stack 212. Controlling the voltage VbatP at the positive terminal 220 of the battery cell or cell stack 212 in this way ensures that the state of charge of the battery 210 is not materially altered during the EIS operation.

While the small AC stimulus voltage signal is being applied to the battery 210, the processing subsystem 246 generates one or more impedance measurements for the battery 210 based on the digital signals output by the first (current sense) ADC circuitry 244 and the second (voltage sense) ADC circuitry 258.

Thus, the alternative configuration 300 of FIG. 3 can be used to perform bias free potentiostatic EIS.

In a variant of the example method described above, instead of controlling the second protection switch 234, the linear charge loop control circuitry 264 may control the external switch 292 to control the voltage applied to the positive terminal 220 of the battery 210. In such a variant, the output of the linear charge loop control circuitry 264 may be coupled to a control (e.g. gate) terminal of the external switch 292 and decoupled from the control terminal of the second protection switch 234 when the method is being performed. In this variant, the first and second protection switches 232, 234 are switched on while the method is being performed.

In the example method described above with reference to FIG. 3, the DC reference voltage is generated by the low pass filter 350, based on the digital signal Vbat_smp indicative of the battery voltage Vbat. In this arrangement, the corner frequency of the low pass filter 350 should be much lower than the lowest EIS frequency excited (i.e. the lowest frequency of the AC voltage signal output by the charging waveform generator 254). This method avoids a potentially high inrush current that could occur if a set DC voltage reference did not correspond to the battery open circuit voltage when a potentiostatic EIS measurement is instigated.

However, in an alternative approach the DC reference voltage may be a fixed target battery voltage, which may be set by a user, for example. This target reference voltage (or an indication of the target reference voltage) may be stored in a memory subsystem (e.g. a register) of the system 200 or a host device that incorporates the system 200. Thus, in such an approach the low pass filter 350 may not be used, and the second input of the adder 252 may instead be coupled (via appropriate circuitry, if necessary) to an output of the memory subsystem so as to receive the target reference voltage or an indication of the target reference voltage.

In a further method, the system 200 may be used to perform dynamic EIS for a battery, e.g. for dynamic power prediction (DPP).

To support DPP, it may be necessary or desirable to excite the battery 210 during a normal discharge or charging operation to supplement a dynamic load on the battery 210 in order to permit estimation of the battery impedance Zbat at one or more excitation frequencies.

In normal operation of a host device incorporating the system 200, the first and second protection switches 232, 234 are both switched fully on. A battery current Ibat is supplied to the battery 210, e.g. from the charger 290 (or drawn from the battery 210 by the system load). The battery current Ibat may not be sinusoidal, and may not be DC-free. Additionally, the battery current Ibat may be of a much higher amplitude than the amplitude of the stimulus current used in the galvanostatic EIS methods discussed above.

To facilitate estimation of the battery impedance Zbat in a dynamic EIS operation, the shunt switch 274 may be activated to discharge the battery cell or cell stack 212 in response to a request from a DPP engine 360 (which may be part of the system 200, or alternatively may be part of the host device).

The shunt switch 274 may be pulsed (i.e. repeatedly switched on and off), e.g. in response to suitable control signals output by the second on/off control circuitry 278, to modulate a discharge current.

Alternatively, the impedance of the shunt switch 274 may be controlled, e.g. in response to a control signal output by the linear discharge loop control circuitry 280, to modulate the discharge current. The shunt switch 274 may be controlled to achieve an AC discharge current having a fixed frequency, an AC discharge current having a plurality of different frequencies, or an AC discharge current whose frequency varies (e.g. is swept or stepped) over a defined range (e.g. e.g. 50 kHz to 1 mHz) over a defined period of time.

As the shunt switch 274 is being controlled to modulate the discharge current in this way, thus providing a stimulus signal to the battery 210, the processing subsystem 246 receives the first digital input signal Ibat_smp indicative of the current Ibat through the battery cell or cell stack 212 and the second digital input signal Vbat_smp indicative of the battery voltage Vbat (of the battery pack voltage) and generates the output Zbat indicative of the impedance of the battery cell or cell stack 212 (at the frequency or frequencies of the AC discharge current) based on the digital input signals, by dividing the battery voltage Vbat indicated by the second digital input signal by the battery current Ibat indicated by the first digital input signal. The output Zbat can be used by the DPP engine 360 to generate a dynamic power prediction.

In the system 200 described above with reference to FIGS. 2 and 3, the protection subsystem 230 and fuel gauge subsystem 240 may be pre-existing parts of a battery pack. The protection subsystem 230 is operable, in normal use of the battery pack, to control charging of the battery 210. The charging waveform generator 254 may be used, in normal operation of the battery pack, to provide a charging waveform for recovering the battery 210 from a deeply discharged state. The fuel gauge subsystem 240 is operable, in normal use of the battery pack, to provide an estimate of a state of charge of the battery 210.

Re-using or repurposing these pre-existing subsystems to perform the EIS methods described above is a cost-effective way of implementing EIS functionality in a battery pack without requiring significant expenditure on additional components or circuitry. Additionally, using the second switch 234 of the protection subsystem 230 (or the external switch 292) to control the stimulus signal (AC voltage or current) applied to the battery 210 obviates the need for an on-chip power sink, thus avoids the measurement inaccuracy problems described above that can arise when an on-chip power sink is used for performing EIS measurements.

The analog front end circuitry 242, first and second ADC circuitry 242, 258, coulomb counter circuitry 248, first multiplexer circuitry 256, linear charge loop control circuitry 264 and on/off control circuitry 262 may be implemented in analog integrated circuitry, for example in a fuel gauge integrated circuit (IC) that is coupled to the battery 210 and that may be provided as part of a battery pack incorporating the battery 210. Thus, the analog front end circuitry 242, first and second ADC circuitry 242, 258, coulomb counter circuitry 248, first multiplexer circuitry 256, linear charge loop control circuitry 264 and on/off control circuitry 262 may be “on-chip” analog circuitry.

The processing subsystem 246, offset controller 250, adder 252, charging waveform generator 254 and low-pass filter 350 may be implemented in digital integrated circuitry, e.g. as on-chip digital circuitry of a fuel gauge IC of the kind described above.

Alternatively, the processing subsystem 246, offset controller 250, adder 252, charging waveform generator 254 and low-pass filter 350 may be implemented in software executing on suitable processing circuitry. The processing circuitry may comprise, for example, one or more processor ICs, one or more application specific integrated circuits (ASICs), digital signal processors (DSPs) or field programmable gate arrays (FPGAs).

The controllable shunt path 270 may be implemented in integrated circuitry, e.g. as on-chip circuitry of a fuel gauge IC of the kind described above. Alternatively, the shunt switch 274 may be implemented on-chip and the shunt resistor 272 may be an off-chip component (i.e. external to an IC incorporating the shunt switch 274). In a further alternative example, the shunt resistor 272 may be implemented on-chip and the shunt switch 274 may be implemented off-chip, e.g. by an off-chip FET. In a still further alternative example, both the shunt resistor 272 and the shunt switch 274 may be implemented off-chip.

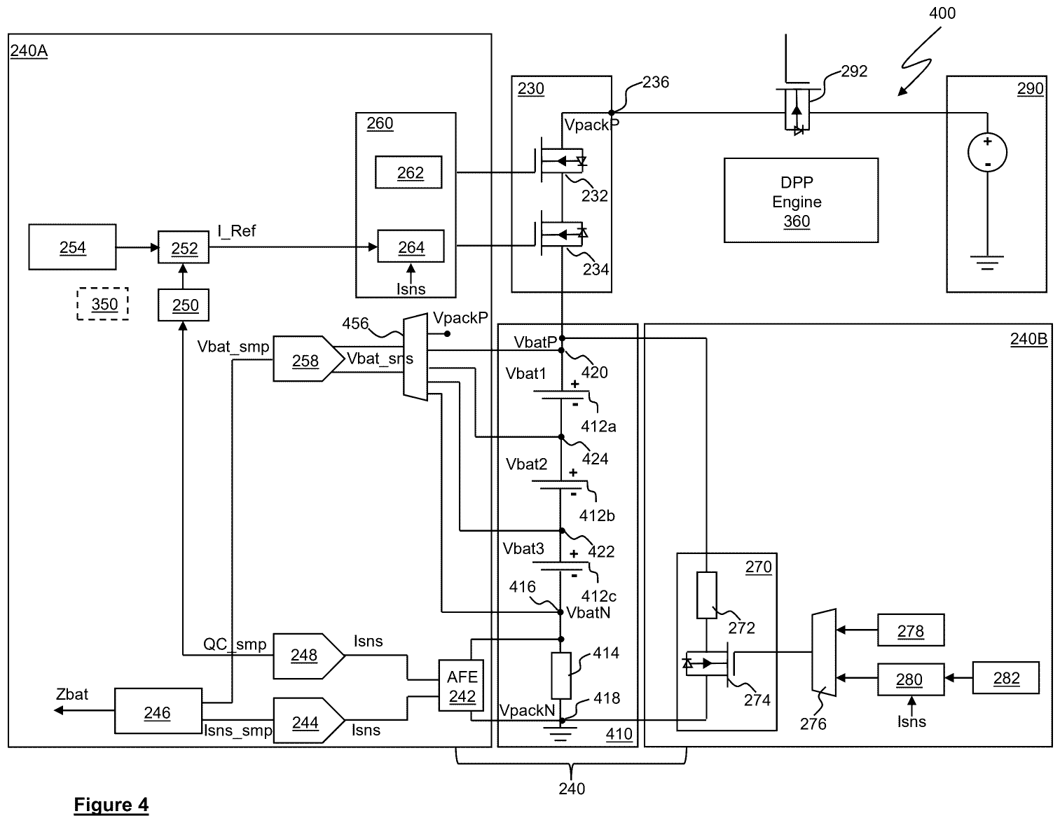

FIG. 4 is a schematic diagram showing an alternative system for performing EIS for a battery according to the present disclosure.

The alternative system, shown generally at 400 in FIG. 4, has a number of features in common with the system 200 of FIG. 2. Such common features are denoted by common reference numerals in FIGS. 2 and 4, and will not be described again in detail here, for the sake of clarity and brevity.

The alternative system 400 of FIG. 4 differs from the system 200 of FIG. 2 in that it is able to perform EIS for each cell of a multi-cell battery 410.

In FIG. 4 the battery 410 is shown as comprising a cell stack having first, second and third battery cells 412a, 412b, 412c coupled in series between a negative terminal 416 and a positive terminal 420, with a current sense resistor 414 being coupled in series with the cell stack between the negative terminal 416 of the cell stack and a ground or negative terminal 418 of the battery. However, it will be appreciated by those of ordinary skill in the art that the battery 410 could comprise any number of series-coupled cells.

In the alternative system 400 of FIG. 4, the shunt path is coupled in parallel with the battery 410, between the positive terminal 420 and the ground or negative terminal 418 of the battery 410.

To facilitate performing EIS for each cell of the battery 410, the fuel gauge subsystem 240 of the alternative system 400 includes first multiplexer circuitry 456 having five inputs and two outputs, in place of the three-input, two-output first multiplexer circuitry 256 of the system 200 of FIG. 2.

A first input of the first multiplexer circuitry 456 is coupled to a negative terminal 416 of the cell stack so as to receive a receive a voltage VbatN of the negative terminal 416. A second input of the first multiplexer circuitry 456 is coupled to a node 422 between a negative terminal of the second battery cell 412b and a positive terminal of the third battery cell 412c, so as to receive a voltage Vbat3 at the positive terminal of the third battery cell 412c. A third input of the first multiplexer circuitry 456 is coupled to a node 424 between a negative terminal of the first battery cell 412a and a positive terminal of the second battery cell 412b, so as to receive a voltage Vbat2 at the positive terminal of the second battery cell 412b. A fourth input of the first multiplexer circuitry 456 is coupled to the positive terminal 420 of the cell stack so as to receive a voltage Vbat1 at a positive terminal of the first battery cell 412a. A fifth input of the first multiplexer circuitry 456 is coupled to a positive terminal of the battery pack in which the battery 410, protection subsystem 230 and fuel gauge subsystem 240 are incorporated so as to receive a voltage VpackP of the positive terminal of the battery pack.

The first and second outputs of the first multiplexer circuitry 456 are coupled to the differential first and second inputs of the second (voltage sense) ADC circuitry 258. The first multiplexer circuitry 456 is operative to selectively couple its first, second, third, fourth and fifth inputs to its first and second outputs, such that a differential output voltage signal Vbat_sns output by the first multiplexer circuitry 456 is equal to a difference between the voltages at the selected inputs of the first multiplexer circuitry 456.

When the first and second inputs of the first multiplexer circuitry 456 are coupled, respectively, to its first and second outputs, the voltages VbatN and Vbat3 are supplied to the differential first and second inputs of the second ADC circuitry 258, such that the second ADC circuitry 258 outputs a digital signal Vbat_smp indicative of the voltage Vbat across the third battery cell 412c (i.e. Vbat3-VbatN).

When the second and third inputs of the first multiplexer circuitry 456 are coupled, respectively, to its first and second outputs, the voltages Vbat3 and Vbat2 are supplied to the differential first and second inputs of the second ADC circuitry 258, such that the second ADC circuitry 258 outputs a digital signal Vbat_smp indicative of an approximation of a voltage across the second battery cell 412b (i.e. Vbat2-Vbat3).

When the third and fourth inputs of the first multiplexer circuitry 456 are coupled, respectively, to its first and second outputs, the voltages Vbat2 and Vbat1 are supplied to the differential first and second inputs of the second ADC circuitry 258, such that the second ADC circuitry 258 outputs a digital signal Vbat_smp indicative of an approximation of a voltage across the second battery cell 412b (i.e. Vbat1-Vbat2).

When the first and fourth inputs of the first multiplexer circuitry 456 are coupled, respectively, to its first and second outputs, the voltages VbatN and VbatP are supplied to the differential first and second inputs of the second ADC circuitry 258, such that the second ADC circuitry 258 outputs a digital signal Vbat_smp indicative of an approximation of a voltage across the cell stack comprising the first, second and third battery cells 412a, 412b, 412c (i.e. VbatP-VbatN).

When the first and fifth inputs of the first multiplexer circuitry 456 are coupled, respectively, to its first and second outputs, the voltages VbatN and VpackP are supplied to the differential first and second inputs of the second ADC circuitry 258, such that the second ADC circuitry 258 outputs a digital signal Vbat_smp indicative of an approximation of a voltage across the battery pack (i.e. VpackP-VbatN).

Thus, the first multiplexer circuitry 456 is operative to output a differential voltage Vbat_sns indicative of the voltage of either a selected battery cell 412a, 412b, 412c, the entire cell stack, or the battery pack, depending on which of its inputs are selected by the first multiplexer circuitry 456.

The processing subsystem 246 in the alternative system 400 receives, from the first (current sense) ADC circuitry 244, a first digital input signal Isns_smp indicative of the current Ibat through the cell stack and, from the second (voltage sense) ADC circuitry 258, a second digital input signal Vbat_smp indicative of the voltage of the selected cell or cells 412a, 412b, 412c. The processing subsystem 246 is configured to generate an output Zbat indicative of the impedance of the selected cell or cells 412a, 412b, 412c based on the digital input signals, by dividing the voltage indicated by the second digital input signal Vbat_smp by the current indicated by the first digital input signal Isns_smp.

The alternative system 400 is operable to perform galvanostatic EIS of the battery 410 or an individual battery cell 412a, 412b, 412c, by applying a small AC stimulus current signal to the battery 410 using the first or second method described above with reference to FIG. 2.

To perform galvanostatic EIS of the battery 410 using the first or second method described above with reference to FIG. 2, a suitable control signal is supplied to the first multiplexer circuitry 456 to cause the first multiplexer circuitry 456 to couple its first output to its first input and to couple its second output to its fourth input.

As discussed above, in this configuration, the differential output signal Vbat_sns output by the first multiplexer circuitry 456 is representative of (e.g. equal to) the voltage across the cell stack comprising the first, second and third battery cells 412a, 412b, 412c. The digital signal Vbat_smp output by the second (voltage sense) ADC circuitry 258 is thus representative of an approximation of the voltage of the battery 410. The digital signal Isns_smp output by the first (current sense) ADC circuitry 244 is indicative of the current through the battery 410.

As in the system 200 described above with reference to FIG. 2, in the first method for performing galvanostatic EIS for the battery 410, while a biased small amplitude AC stimulus signal is being applied to the battery 410, the processing subsystem 246 generates one or more impedance measurements for the battery 410 based on the digital signals output by the first (current sense) ADC circuitry 244 and the second (voltage sense) ADC circuitry 258.

Similarly, in the second method for performing galvanostatic EIS for the battery 410, while a small amplitude AC discharge signal is being applied to the battery 410, the processing subsystem 246 generates one or more impedance measurements for the battery 410 based on the digital signals output by the first (current sense) ADC circuitry 244 and the second (voltage sense) ADC circuitry 258.

To perform galvanostatic EIS of the first battery cell 412a using the first or second method described above with reference to FIG. 2, a suitable control signal is supplied to the first multiplexer circuitry 456 to cause the first multiplexer circuitry 456 to couple its first output to its third input and to couple its second output to its fourth input.

As discussed above, in this configuration, the differential output signal Vbat_sns output by the first multiplexer circuitry 456 is representative of (e.g. equal to) the voltage across the first battery cell 412a. The digital signal Vbat_smp output by the second (voltage sense) ADC circuitry 258 is thus representative of an approximation of the voltage of the first battery cell 412a. The digital signal Isns_smp output by the first (current sense) ADC circuitry 244 is indicative of the current through the battery 410 (and thus the current through the first cell 412a).

In the first method for performing galvanostatic EIS for the first battery cell 412a, while a biased small amplitude AC stimulus signal is being applied to the battery 410, the processing subsystem 246 generates one or more impedance measurements for the first battery cell 412a based on the digital signals output by the first (current sense) ADC circuitry 244 and the second (voltage sense) ADC circuitry 258.

Similarly, in the second method for performing galvanostatic EIS for the first battery cell 412a, while a small amplitude AC discharge signal is being applied to the battery 410, the processing subsystem 246 generates one or more impedance measurements for the first battery cell 412a based on the digital signals output by the first (current sense) ADC circuitry 244 and the second (voltage sense) ADC circuitry 258.

As will be apparent to those or ordinary skill in the art, to perform galvanostatic EIS of the second or third battery cells 412b, 412c, suitable control signals are supplied to the first multiplexer circuitry 456 to cause it to couple its outputs to the appropriate ones of its inputs such that the digital signal Vbat_smp output by the second (voltage sense) ADC circuitry 258 is representative of an approximation of the voltage of the second or third battery cell 412b, 412c as appropriate.

The alternative system 400 is also operable to perform bias free potentiostatic EIS of the battery 410 or an individual battery cell 412a, 412b, 412c, by applying a small AC stimulus current signal to the battery 410 using the method described above with reference to FIG. 3.

To perform bias free potentiostatic EIS of the battery 410 using the method described above with reference to FIG. 3, a suitable control signal is supplied to the first multiplexer circuitry 456 to cause the first multiplexer circuitry 456 to couple its first output to its first input and to couple its second output to its fourth input.

As discussed above, in this configuration, the differential output signal Vbat_sns output by the first multiplexer circuitry 456 is representative of (e.g. equal to) the voltage across the cell stack comprising the first, second and third battery cells 412a, 412b, 412c. The digital signal Vbat_smp output by the second (voltage sense) ADC circuitry 258 is thus representative of an approximation of the voltage of the battery 410. The digital signal Isns_smp output by the first (current sense) ADC circuitry 244 is indicative of the current through the battery 410.

As in the method described above with reference to FIG. 3, while a small AC stimulus voltage signal is being applied to the battery 410, the processing subsystem 246 generates one or more impedance measurements for the battery 410 based on the digital signals output by the first (current sense) ADC circuitry 244 and the second (voltage sense) ADC circuitry 258.

To perform bias free potentiostatic EIS the first battery cell 412a using the first or second method described above with reference to FIG. 2, a suitable control signal is supplied to the first multiplexer circuitry 456 to cause the first multiplexer circuitry 456 to couple its first output to its third input and to couple its second output to its fourth input.

As discussed above, in this configuration, the differential output signal Vbat_sns output by the first multiplexer circuitry 456 is representative of (e.g. equal to) the voltage across the first battery cell 412a. The digital signal Vbat_smp output by the second (voltage sense) ADC circuitry 258 is thus representative of an approximation of the voltage of the first battery cell 412a. The digital signal Isns_smp output by the first (current sense) ADC circuitry 244 is indicative of the current through the battery 410 (and thus the current through the first cell 412a).

While a small AC stimulus voltage signal is being applied to the battery 410, the processing subsystem 246 generates one or more impedance measurements for the battery 410 based on the digital signals output by the first (current sense) ADC circuitry 244 and the second (voltage sense) ADC circuitry 258.

As will be apparent to those or ordinary skill in the art, to perform bias free potentiostatic EIS the second or third battery cells 412b, 412c, suitable control signals are supplied to the first multiplexer circuitry 456 to cause it to couple its outputs to the appropriate ones of its inputs such that the digital signal Vbat_smp output by the second (voltage sense) ADC circuitry 258 is representative of an approximation of the voltage of the second or third battery cell 412b, 412c as appropriate.

The alternative system 400 is further operable to perform dynamic EIS of the battery 410, by modulating a discharge current using the shunt switch 274 and determining (by the processing subsystem 246) an impedance of the battery 410 at one or more frequencies of the discharge current, as described above.

In the methods for performing EIS measurements of individual battery cells 412a, 412b, 412c described above with reference to FIG. 4, an individual battery cell 412a, 412b, 412c is selected by transmitting a suitable control signal to the first multiplexer circuitry 456. Thus, an EIS measurement can be performed for only a single one of the battery cells 412a, 412b, 412c at a time, such that if EIS measurements are desired for all the battery cells 412a, 412b, 412c, they must be performed sequentially.

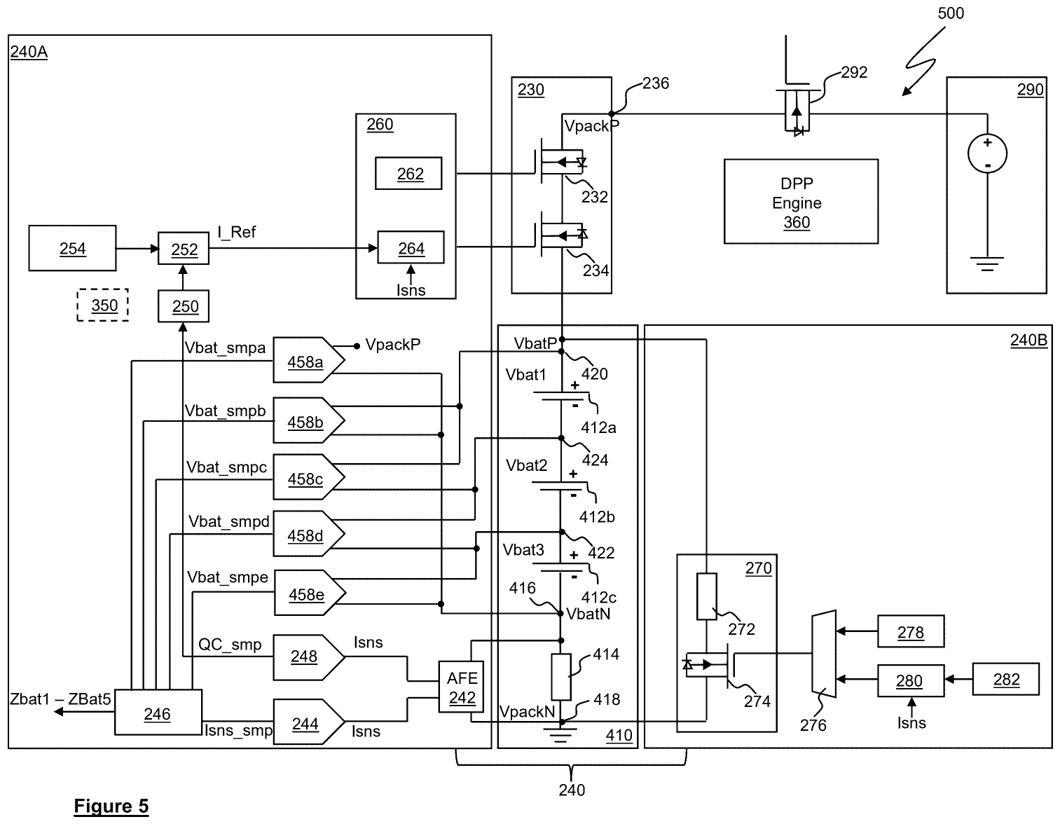

In an alternative example system, shown generally at 500 in FIG. 5, EIS measurements can be performed for each of the individual battery cells 412a, 412b, 412c in parallel.

In this approach, instead of selectively coupling a single cell to the differential inputs of the second (voltage sense) ADC circuitry 458, a plurality (in this example 5) of instances of voltage sense ADC circuitry 458a-458e are provided, each having differential inputs coupled to different nodes of the battery 410 so as to generate respective digital output signals Vbat_smpa-Vbat_smpe representative of approximations of voltages at the different nodes of the battery 410.

Thus, in the example shown in FIG. 5, a first instance of voltage sense ADC circuitry 458a is configured to receive the voltages VbatN and Vpack and to output a digital signal Vbat_smpa representative of an approximation of a voltage of the battery pack to a second input of the processing subsystem 246. A second instance of voltage sense ADC circuitry 458b is configured to receive the voltages VbatN and VbatP and to output a digital signal Vbat_smpb representative of an approximation of a voltage of the battery 410 to a third input of the processing subsystem 246. A third instance of voltage sense ADC circuitry 458c is configured to receive the voltages Vbat1 and Vbat2 and to output a digital signal Vbat_smpc representative of an approximation of a voltage of the first battery cell 412a to a third input of the processing subsystem 246. A fourth instance of voltage sense ADC circuitry 458d is configured to receive the voltages Vbat2 and Vbat3 and to output a digital signal Vbat_smpc representative of an approximation of a voltage of the second battery cell 412b to a fourth input of the processing subsystem 246. A fifth instance of voltage sense ADC circuitry 458e is configured to receive the voltages Vbat3 and VbatN and to output a digital signal Vbat_smpe representative of an approximation of a voltage of the third battery cell 412c to a fifth input of the processing subsystem 246.

When performing an EIS measurement using any of the methods described above, the processing subsystem 246 receives the digital signals Vbat_smpa-Vbat_smpe output by the instances of voltage sense ADC circuitry 458a-458e and the digital signal Isns_smp output by the first (current sense) ADC circuitry 244 indicative of the current through the battery 410. The processing subsystem is operable to generate outputs Zbat1-Zbat5 indicative of the impedance of the battery pack, the battery 410 and each of the battery cells 412a, 412b, 412c based on the digital input signals, by dividing each of the voltages indicated by the digital signals Vbat_smpa-Vbat_smpe by the current indicated by the digital input signal Isns_smp output by the first (current sense) ADC circuitry 244.

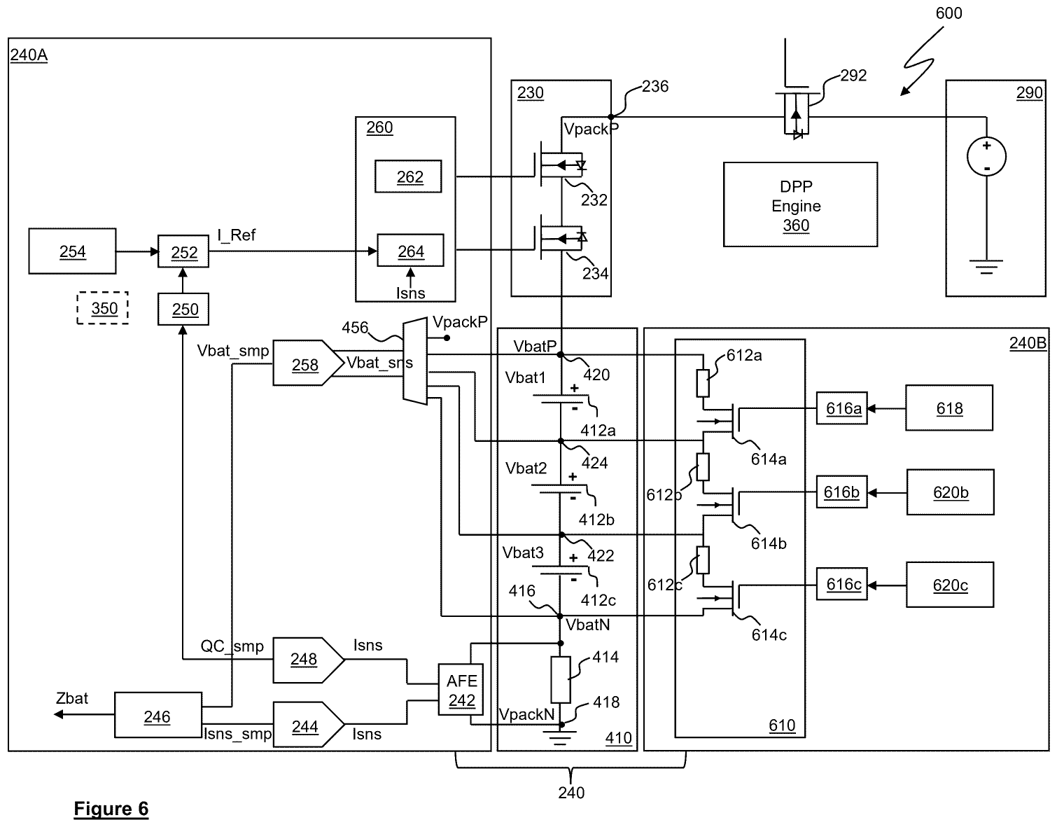

FIG. 6 is a schematic diagram showing a further alternative system for performing EIS for a battery according to the present disclosure.

The further alternative system, shown generally at 600 in FIG. 6, has a number of features in common with the alternative system 400 of FIG. 4. Such common features are denoted by common reference numerals in FIGS. 4 and 6, and will not be described again in detail here, for the sake of clarity and brevity.

The further alternative system 600 differs from the alternative system 400 of FIG. 4 in that it does not include the controllable shunt path 270. Instead, shunt switches (and, in some examples, shunt resistors) that are provided as part of a cell balancing circuit 610 of the system 600 are used to provide a controllable shunt path. Using the shunt switches (and, where applicable, the shunt resistors) that are already present in the battery system 600 to provide a controllable shunt path obviates the need to provide a dedicated shunt path 270 of the kind described above and shown in FIGS. 2-5, thus reducing the cost and complexity of the system 600.

In the example shown in FIG. 6, the cell balancing circuit 610 includes a series combination of a first shunt resistor 612a and a first shunt switch 614a forming a first branch of the cell balancing circuit, which is coupled in parallel with the first battery cell 412a of the battery 410.

The cell balancing circuit 610 further includes a series combination of a second shunt resistor 612b and a second shunt switch 614b forming a second branch of the cell balancing circuit 610, which is coupled in parallel with the second battery cell 412b of the battery 410, and a series combination of a third shunt resistor 612c and a third shunt switch 614c forming a third branch of the cell balancing circuit 610, which is coupled in parallel with the third battery cell 412c of the battery 410. However, in other examples the shunt resistors 612a, 612b, 612c may be omitted. In such examples, the on-resistance of one or more of the shunt switches 614a, 614b, 614c may be used to provide a shunt resistance. The first, second and third shunt switches 614a, 614b, 614c may be FETs, for example.

An output of first current control circuitry 616a is coupled to a control terminal (e.g. a gate) of the first shunt switch 614a. Similarly, an output of second current control circuitry 616b is coupled to a control terminal (e.g. a gate) of the second shunt switch 614b, and an output of third current control circuitry 616c is coupled to a control terminal (e.g. a gate) of the second shunt switch 614c.

An input of the first current control circuitry 616a is coupled to an output of a discharge waveform generator 618, which is similar to the discharge waveform generator 282 of the system 200 of FIG. 2.

An input of the second current control circuitry 616b is coupled to an output of a first bypass current generator 620b, and an input of the third current control circuitry 616c is coupled to an output of a second bypass current generator 620c.

When used for cell balancing, the shunt switches 614a, 614b, 614c may be activated (e.g. switched on) individually to shunt current around individual battery cells 412a, 412b, 412c of the battery 410.

When used to provide a shunt path, the shunt switches 614a, 614b, 614c are activated (e.g. switched on) simultaneously to shunt current around the cell stack comprised of the first, second and third battery cells 412a, 412b, 412c.

The current in each of the first, second and third branches of the cell balancing circuit 610 should match to prevent (or at least reduce) changes to the charge balance between the battery cells 412a, 412b, 412c. Such matching of the current in the branches can be achieved in different ways. For example, if the shunt switches 612a, 612b, 612c are operated in an on/off manner, a precision resistor in series with each shunt switch 612a, 612b, 612c can help to reduce any current mismatch between the branches. If the shunt switches 612a, 612b, 612c are operated through current control, the shunt switches 612a, 612b, 612c can use a common reference for good current matching between the branches.

The further alternative system 600 is operable to perform galvanostatic EIS of the battery 410 or an individual battery cell 412a, 412b, 412c, by applying a small AC stimulus current signal to the battery 410 as described above with reference to FIG. 4.

When galvanostatic EIS is performed using the second method described above, the shunt current is modulated by the discharge waveform generator 618, which generates a suitable discharge waveform that is applied (via the first current control circuitry 616a) to the control terminal of the first shunt switch 614a. The second and third shunt switches 614b, 614c are switched on in response to suitable control signals, generated by the first and second bypass current generators 620b, 620c respectively, and applied to the respective control terminals of the second and third shunt switches 614b, 614c by the second and second and third current control circuitry 616b, 616c.

The further alternative system 600 is also operable to perform bias free potentiostatic EIS of the battery 410 or an individual battery cell 412a, 412b, 412c, by applying a small AC stimulus current signal to the battery 410 in the manner described above with reference to FIG. 4.

The further alternative system 600 is further operable to perform dynamic EIS of the battery 410, by modulating a discharge current using the first shunt switch 614a (while holding the second and third shunt switches 612b, 612c closed, i.e. switched on) and determining (by the processing subsystem 246) an impedance of the battery 410 at one or more frequencies of the discharge current, as described above.

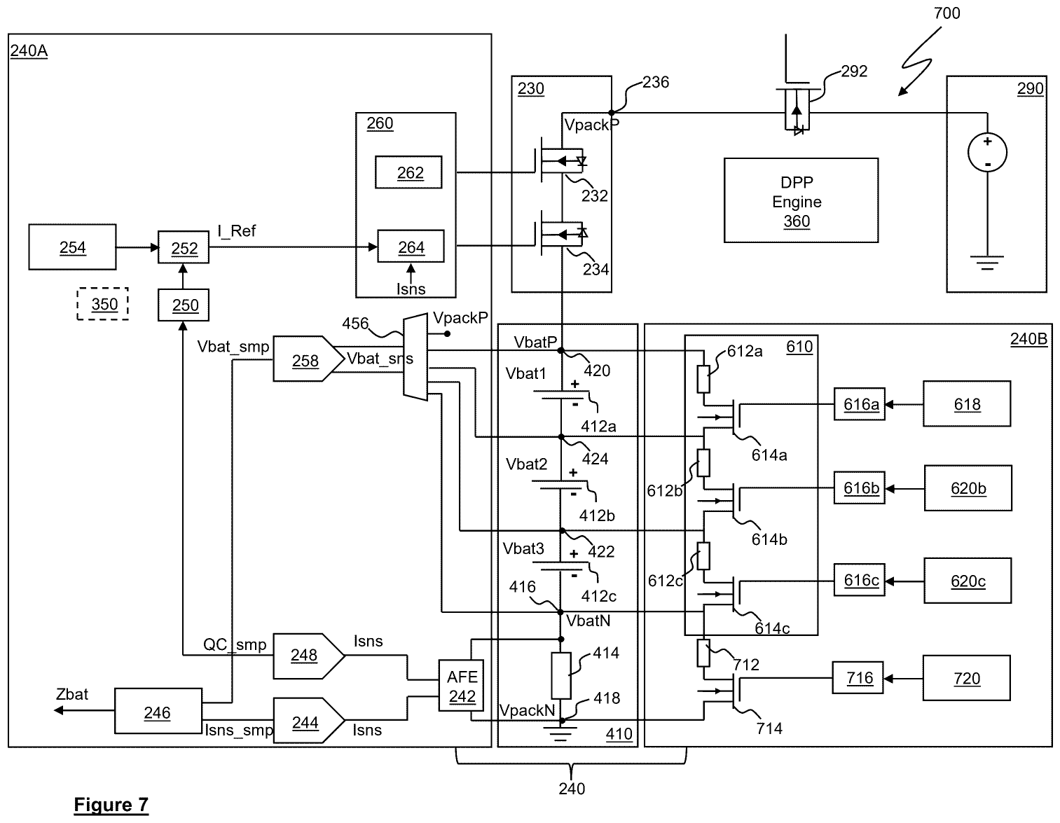

FIG. 7 is a schematic diagram showing another alternative system for performing EIS for a battery according to the present disclosure.

The another alternative system, shown generally at 700 in FIG. 7, has a number of features in common with the further alternative system 600 of FIG. 6. Such common features are denoted by common reference numerals in FIGS. 6 and 7, and will not be described again in detail here, for the sake of clarity and brevity.

The another alternative system 700 of FIG. 7 differs from the further alternative system 600 of FIG. 6 in that it includes a fourth branch coupled in parallel with the current sense resistor 414, where the fourth branch comprises a series combination of a fourth shunt resistor 712 and a fourth shunt switch 714. A control (e.g. gate) terminal of the fourth shunt switch is coupled to an output of fourth current control circuitry 716, and an input of the fourth current control circuitry 716 is coupled to an output of a third bypass current generator 720.

The addition of the fourth branch in the another alternative system 700 permits more accurate measurement of the current through the battery 410 when the (shunt path provided by the cell balancing circuit 610 is active) than is possible in the further alternative system 600 of FIG. 6.

This is because in the further alternative system 600, the voltage across the current sense resistor 414 represents the sum of the current through the first, second and third battery cells 412a, 412b, 412a and the current through the shunt path provided by the cell balancing circuit 610, since the shunt path provided by the cell balancing circuit 610 only shunts current around the battery cells 412a, 412b, 412c.

In contrast, the fourth branch in the another alternative system 700 of FIG. 7 permits current to be shunted around the series combination of the first, second and third battery cells 412a, 412b, 412c and the current sense resistor 414. Thus, when the fourth shunt switch 714 is activated (e.g. switched on), the voltage across the current sense resistor 414 in the another alternative system 700 represents only the current through the first, second and third battery cells 412a, 412b, 412c.

Thus, the cell balancing circuit 610 can be used for cell balancing in the another alternative system 700 of FIG. 7, but when a shunt path is required, the fourth shunt switch 714 can be activated (e.g. switched on) to shunt current around the battery cells 412a, 412b, 412c and the current sense resistor 414, such that the current through the cell stack (comprising the battery cells 412a, 412b, 412c) can be accurately detected. With the shunt path, including the fourth shunt switch 714, activated, a signal Isns that is an accurate representation of the battery current Ibat can be supplied to the linear charge loop control circuitry 264.

The circuitry described above with reference to the accompanying drawings may be incorporated in a host device such as a laptop, notebook, netbook or tablet computer, a gaming device such as a games console or a controller for a games console, a virtual reality (VR) or augmented reality (AR) device, a mobile telephone, a portable audio player or some other portable device, or may be incorporated in an accessory device for use with a laptop, notebook, netbook or tablet computer, a gaming device, a VR or AR device, a mobile telephone, a portable audio player or other portable device.

The skilled person will recognise that some aspects of the above-described apparatus and methods may be embodied as processor control code, for example on a non-volatile carrier medium such as a disk, CD- or DVD-ROM, programmed memory such as read only memory (Firmware), or on a data carrier such as an optical or electrical signal carrier. For many applications embodiments of the invention will be implemented on a DSP (Digital Signal Processor), ASIC (Application Specific Integrated Circuit) or FPGA (Field Programmable Gate Array). Thus the code may comprise conventional program code or microcode or, for example code for setting up or controlling an ASIC or FPGA. The code may also comprise code for dynamically configuring re-configurable apparatus such as re-programmable logic gate arrays. Similarly the code may comprise code for a hardware description language such as Verilog™ or VHDL (Very high speed integrated circuit Hardware Description Language). As the skilled person will appreciate, the code may be distributed between a plurality of coupled components in communication with one another. Where appropriate, the embodiments may also be implemented using code running on a field-(re)programmable analogue array or similar device in order to configure analogue hardware.

Note that as used herein the term module shall be used to refer to a functional unit or block which may be implemented at least partly by dedicated hardware components such as custom defined circuitry and/or at least partly be implemented by one or more software processors or appropriate code running on a suitable general purpose processor or the like. A module may itself comprise other modules or functional units. A module may be provided by multiple components or sub-modules which need not be co-located and could be provided on different integrated circuits and/or running on different processors.

As used herein, when two or more elements are referred to as “coupled” to one another, such term indicates that such two or more elements are in electronic communication or mechanical communication, as applicable, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative. Accordingly, modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

Although exemplary embodiments are illustrated in the figures and described below, the principles of the present disclosure may be implemented using any number of techniques, whether currently known or not. The present disclosure should in no way be limited to the exemplary implementations and techniques illustrated in the drawings and described above.

Unless otherwise specifically noted, articles depicted in the drawings are not necessarily drawn to scale.

All examples and conditional language recited herein are intended for pedagogical objects to aid the reader in understanding the disclosure and the concepts contributed by the inventor to furthering the art, and are construed as being without limitation to such specifically recited examples and conditions. Although embodiments of the present disclosure have been described in detail, it should be understood that various changes, substitutions, and alterations could be made hereto without departing from the spirit and scope of the disclosure.

Although specific advantages have been enumerated above, various embodiments may include some, none, or all of the enumerated advantages. Additionally, other technical advantages may become readily apparent to one of ordinary skill in the art after review of the foregoing figures and description.

It should be noted that the above-mentioned embodiments illustrate rather than limit the invention, and that those skilled in the art will be able to design many alternative embodiments without departing from the scope of the appended claims. The word “comprising” does not exclude the presence of elements or steps other than those listed in a claim, “a” or “an” does not exclude a plurality, and a single feature or other unit may fulfil the functions of several units recited in the claims. Any reference numerals or labels in the claims shall not be construed so as to limit their scope.

1. A system for performing electrochemical impedance spectroscopy for a battery, the system comprising:
a switch operable to apply an AC stimulus signal to the battery;
current monitor circuitry configured to be coupled to the battery and to provide a battery current signal indicative of a current through the battery;
voltage monitor circuitry configured to be coupled to the battery and to output a battery voltage signal indicative of a voltage across at least one cell of the battery;
a processing subsystem having a first input coupled to an output of the current monitoring circuitry and a second input coupled to an output of the voltage monitoring circuitry, wherein the processing subsystem is configured to determine an impedance of the at least one cell of the battery based on the battery current signal and the battery voltage signal while the AC stimulus signal is being applied to the battery.

2. The system of claim 1, wherein the battery, switch, voltage monitor circuitry, current monitor circuitry and processing subsystem are parts of a battery pack.

3. The system of claim 1, wherein the battery, voltage monitor circuitry, current monitor circuitry and processing subsystem are parts of a battery pack, and wherein the switch is external to the battery pack.

4. The system of claim 2, wherein the current monitor circuitry and the voltage monitor circuitry are parts of a fuel gauge subsystem of the battery pack, and wherein the switch is part of a protection subsystem of the battery pack, wherein in normal operation of the battery pack the protection subsystem is operable to control current into and out of the battery.

5. The system of claim 1, wherein the battery comprises the at least one cell and a current sense resistor coupled in series with the at least one cell.

6. The system of claim 1, further comprising control circuitry configured to control operation of the switch based on a reference current or a reference voltage input to the control circuitry.

7. The system of claim 6, wherein the reference current comprises an AC component and a DC component, and wherein the control circuitry is configured to control operation of the switch to minimise a difference between the reference current and the current through the battery.

8. The system of claim 7, further comprising a charging waveform generator configured to provide the AC component of the reference current.

9. The system of claim 7, further comprising coulomb counter circuitry configured to output a signal indicative of a state of charge of the battery, and wherein the DC component of the reference current is based on the signal output by the coulomb counter circuitry.

10. The system of claim 6, wherein the reference voltage comprises an AC component and a DC component, and wherein the linear charge loop control circuitry is configured to control operation of the switch to minimise a difference between the reference voltage and the voltage across the at least one cell of the battery.

11. The system of claim 10, further comprising a charging waveform generator configured to provide the AC component of the reference voltage.

12. The system of claim 10, further comprising a low pass filter operative to generate a filter output signal indicative of the voltage across the at least one cell of the battery, wherein the DC component of the reference voltage is based on the filter output signal or on a predetermined target voltage across the at least one cell of the battery.

13. The system of claim 1, further comprising a shunt path, the shunt path comprising a shunt switch coupled to the at least one cell of the battery and configured to, when activated, shunt current around the at least one cell of the battery.

14. The system of claim 13, wherein:
the battery comprises a plurality of cells coupled in series,
the battery, voltage monitor circuitry, current monitor circuitry and processing subsystem are parts of a battery pack; and
the shunt path comprises one or more switches of a cell balancing circuit of the battery pack.

15. The system of claim 14, wherein the battery comprises the plurality of cells and a current sense resistor coupled in series with the plurality of cells, and wherein the shunt path comprises a further switch coupled in parallel with the current sense resistor and to the one or more switches of the cell balancing circuit.

16. The system of claim 13, wherein the shunt path comprises a shunt resistor coupled in series with the shunt switch.

17. The system of claim 13, wherein the shunt switch is operable to provide the AC stimulus signal to the battery.

18. The system of claim 17, further comprising:
control circuitry; and
a discharge waveform generator,
wherein the control circuitry is configured to receive a discharge waveform from the discharge waveform generator and to control the shunt switch based on the discharge waveform to apply an AC discharge signal to the battery as the AC stimulus signal.

19. The system of claim 18 wherein the control circuitry is configured to configured to control operation of the shunt switch to minimise a difference between the discharge waveform and the current through the battery.

20. The system of claim 5, wherein the current sense circuitry comprises:
the current sense resistor; and
first analog to digital converter (ADC) circuitry having an input coupled to the current sense resistor and configured to generate a digital output signal indicative of the current through the battery.

21. The system of claim 20, wherein the current sense circuitry further comprises analog front end (AFE) circuitry having an input coupled to the current sense resistor and an output coupled to the input of the first ADC circuitry, wherein the AFE circuitry is configured to receive a voltage across the current sense resistor and output an analog AFE output signal indicative of the current through the battery.

22. The system of claim 1, wherein the voltage monitor circuitry comprises:
first multiplexer circuitry having a plurality of inputs and first and second outputs, wherein the first multiplexer circuitry is configured to selectively couple one of its inputs to its first output and another of its inputs to its second output; and
second ADC circuitry having first and second inputs coupled to the first and second outputs, respectively, of the first multiplexer circuitry,
wherein the second ADC circuitry is configured to output a digital signal indicative of one of:
a voltage across a cell of the one or more cells of the battery; or
a voltage across the battery; or
a voltage of a battery pack of which the battery forms part,
dependent upon which of the inputs of the first multiplexer circuitry are coupled to the first and second outputs of the first multiplexer circuitry.

23. The system of claim 1, wherein the battery comprises a plurality of cells coupled in series, and wherein the voltage monitor comprises a plurality of instances of ADC circuitry, each instance of ADC circuitry having first and second inputs coupled to different nodes of the battery, so as to generate respective digital output signals representative of approximations of voltages at the different nodes of the battery.

24. A battery back comprising the system of claim 1.

25. A host device comprising the system of claim 1, wherein the host device comprises a laptop, notebook, netbook or tablet computer, a gaming device, a games console, a controller for a games console, a virtual reality (VR) or augmented reality (AR) device, a mobile telephone, a portable audio player, a portable device, an accessory device for use with a laptop, notebook, netbook or tablet computer, a gaming device, a games console a VR or AR device, a mobile telephone, a portable audio player or other portable device.

26. A system for performing electromagnetic impedance spectroscopy for a battery of a battery pack which comprises a switch operable to control a flow of current into and out of the battery, the system comprising:
control circuitry configured to control the switch to apply an AC stimulus signal to the battery.

27. The system of claim 26, wherein the system further comprises
current monitor circuitry configured to be coupled to the battery and to provide a battery current signal indicative of a current through the battery;
voltage monitor circuitry configured to be coupled to the battery and to output a battery voltage signal indicative of a voltage across at least one cell of the battery;
a processing subsystem having a first input coupled to an output of the current monitoring circuitry and a second input coupled to an output of the voltage monitoring circuitry, wherein the processing subsystem is configured to determine an impedance of the at least one cell of the battery based on the battery current signal and the battery voltage signal while the AC stimulus signal is being applied to the battery.
